(19) United States
(12) Patent Application Publication
(10) Pub. No.: US 2026/0239739 A1
(43) Pub. Date: Aug. 13, 2026

(54) MULTI-SOI STRUCTURE, DEVICE, AND METHODS FOR FORMING AND USING THE SAME

(71) Applicant: Taiwan Semiconductor Manufacturing Company, LTD., Hsinchu (TW)

(72) Inventor: Hung-Te Lin, Hsinchu (TW)

(21) Appl. No.: 19/050,259

(22) Filed: Feb. 11, 2025

(51) Int. Cl. H10D 86/00; H01L 21/762; H10D 86/01

(52) U.S. Cl. CPC H10D 86/201; H10D 86/01; H10P 90/1906; H10W 10/014; H10W 10/061; H10W 10/17; H10W 10/181

(57) ABSTRACT

Multi-SOI substrates and devices comprising the same are provided, along with methods for forming and using the same. The multi-SOI substrate can include a deep silicon-on-insulator (SOI) region and a shallow bias-controlled SOI region and integrated circuits thereon, or two shallow bias-controlled SOI regions. The base substrate is doped in multiple steps to form various layers, including a pickup layer in the shallow SOI region. The pickup layer is formed over a buried dielectric layer, and a semiconducting substrate is present over the pickup layer. A contact layer is formed upon the pickup layer. An isolation region is present over the contact layer, and an electrical contact is formed to the contact layer. The pickup layer is electrically connected to the semiconducting substrate. Other integrated circuits can be formed on the base substrate as well. This results in flexible design layouts.

### BACKGROUND

Integrated circuits can be formed on silicon-on-insulator (SOI) substrates. The substrate is a layered semiconductor-insulator-semiconductor substrate, such as silicon-silicon dioxide-silicon substrate, rather than a bulk semiconductor substrate. Semiconductor devices constructed on the upper silicon layer are electrically isolated from the bulk silicon, which lowers parasitic capacitance, which improves power consumption. In addition, crosstalk arising from capacitive, inductive, and/or conductive coupling between separate devices on the same substrate can be reduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a perspective view showing one deep silicon-on-insulator (SOI) region and one shallow bias-controlled SOI region in one embodiment of a base substrate, in accordance with some embodiments of the present disclosure. Here, the deep SOI region and the shallow bias-controlled SOI region share a common vertical sidewall.

FIG. 1B is a perspective view showing one deep silicon-on-insulator (SOI) region and one shallow bias-controlled SOI region in another embodiment of a base substrate, in accordance with some embodiments of the present disclosure. Here, the deep SOI region and the shallow bias-controlled SOI region are separate from each other, and do not share a common sidewall.

FIG. 1C is a plan view through line C-C of FIG. 1B. FIG. 1D is a plan view through line D-D of FIG. 1B. FIG. 1E is a plan view of a first embodiment through line E-E of FIG. 1B. FIG. 1F is a plan view of a second embodiment through line E-E of FIG. 1B. FIG. 1G is a plan view of a third embodiment through line E-E of FIG. 1B. FIG. 1H is a plan view through line H-H of FIG. 1B.

FIG. 2A and FIG. 2B together form a flow chart illustrating a method for making a base substrate with one deep SOI region and one shallow bias-controlled SOI region, in accordance with some embodiments. The flow chart also illustrates a method for making a base substrate with two shallow bias-controlled SOI regions (one n-type and one p-type), in accordance with some embodiments.

FIG. 3 is a Y-axis cross-sectional view showing the base substrate after doping a first or deep SOI region to form a first or deep buried dopant layer.

FIG. 4 is a Y-axis cross-sectional view showing the base substrate after optional epitaxy to form a first epitaxial layer upon the base substrate.

FIG. 5 is a Y-axis cross-sectional view showing the base substrate after doping both SOI regions to form a buried sidewall dopant layer(s).

FIG. 6A is a Y-axis cross-sectional view showing the base substrate after doping the first shallow SOI region to form a first shallow buried dopant layer.

FIG. 6B is a Y-axis cross-sectional view showing the base substrate after doping the first shallow SOI region with a first dopant type to form a first pickup layer.

FIG. 7 is a Y-axis cross-sectional view showing the base substrate after doping the second shallow SOI region to form a second shallow buried dopant layer and a second pickup layer.

FIG. 8 is a Y-axis cross-sectional view showing the base substrate after doping the two shallow SOI regions to form contact layers that are electrically connected to a pickup layer.

FIG. 9 is a Y-axis cross-sectional view showing the base substrate after optional epitaxy to form a second epitaxial layer upon the base substrate.

FIG. 10 is a Y-axis cross-sectional view showing the base substrate after annealing to convert the buried dopant layers into a first or deep buried dielectric layer, a first shallow buried dielectric layer, and a second shallow buried dielectric layer.

FIG. 11 is a Y-axis cross-sectional view showing the base substrate after etching to form isolation trenches that are connected to (or expose) the vertical sidewalls of the first or deep buried dielectric layer and the shallow buried dielectric layers. Isolation trenches are also formed that expose the two contact layers.

FIG. 12 is a Y-axis cross-sectional view showing the base substrate after the isolation trenches are filled to form isolation regions that electrically isolate semiconducting substrates within the first or deep SOI region and the two shallow SOI regions from the base substrate.

FIG. 13 is a Y-axis cross-sectional view showing the base substrate after N-doping some of the semiconducting substrates on the base substrate .

FIG. 14 is a Y-axis cross-sectional view showing the base substrate after P-doping some of the semiconducting substrates on the base substrate.

FIG. 15 is a Y-axis cross-sectional view showing another embodiment of the base substrate that two active regions of the base substrate, two deep SOI regions, two shallow bias-controlled SOI regions, and two shallow non-bias-controlled SOI regions. The regions are not yet doped.

FIG. 16A is a Y-axis cross-sectional view showing the base substrate of FIG. 15 after doping to form n-wells and p-wells in the base substrate and the semiconducting substrates of the SOI regions. FIG. 16B is a plan view of the base substrate of FIG. 16A.

FIG. 16C is a plan view showing another alternative layout of n-wells and p-wells which can be used in any of the active regions or SOI regions of the base substrate.

FIG. 17A is a Y-axis cross-sectional view showing the two shallow bias-controlled silicon-on-insulator (SOI) regions in the base substrate with transistors formed upon the semiconducting substrates of each SOI region, in accordance with some embodiments of the present disclosure. FIG. 17B is a plan view through line B-B of FIG. 17A.

FIG. 18 is a flow chart illustrating a method for making one or more semiconductor devices in an SOI region, in accordance with some embodiments.

FIG. 19A is a Y-axis cross-sectional view showing three different arrangements of active regions and contact layers in an SOI region in the base substrate, in accordance with some embodiments of the present disclosure. FIG. 19B is a plan view of the structures of FIG. 19A.

FIG. 20A is a Y-axis cross-sectional view showing two different arrangements of active regions in the base substrate, in accordance with some embodiments of the present disclosure. FIG. 20B is a plan view of the structures of FIG. 20A.

FIG. 21A is a Y-axis cross-sectional view showing three different arrangements of active regions in the deep SOI regions of the base substrate, in accordance with some embodiments of the present disclosure. FIG. 21B is a plan view of the structures of FIG. 21A.

FIG. 22 is a flow chart illustrating a method for using a transistor in a shallow bias-controlled SOI region, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The disclosure refers to “length” in the Y-axis and “width” in the X-axis. These terms should not be construed as implying the length must have a greater value than the width.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure refers to temperatures for certain process steps. It is noted that these generally refer to the temperature at which the heat source (e.g. furnace) is set, and do not necessarily refer to the temperature which must be attained by the material being exposed to the heat.

The present disclosure relates to structures which are made up of different layers. When the terms “on” or “upon” or “over” are used with reference to two different layers (including the substrate), they indicate merely that one layer is on or upon or over the other layer. These terms do not require the two layers to directly contact each other, and permit other layers to be between the two layers. For example all layers of the structure can be considered to be “on” or “over” the substrate, even though they do not all directly contact the substrate. The term “directly” may be used to indicate two layers directly contact each other without any layers in between them. In addition, when referring to performing process steps upon the substrate or over the substrate, this should be construed as performing such steps to whatever layers may be present on the substrate as well, depending on the context.

The present disclosure relates to base substrates that include silicon-on-insulator (SOI) regions having different structures, and methods for making and using such base substrates. In some embodiments, the base substrates have a deep SOI region and a shallow bias-controlled SOI region which includes a pickup layer upon the insulator layer. In other embodiments, the base substrates have two shallow bias-controlled SOI regions, one region being n-doped and the other region being p-doped, and each of which includes a pickup layer upon the insulator layer. Such substrates can be produced in-house at a foundry and adapted for specific device needs. These SOI regions can also be combined with non-bias-controlled SOI regions, as well as integrated circuits formed directly in the base substrate. This permits flexible layout structures for different designs.

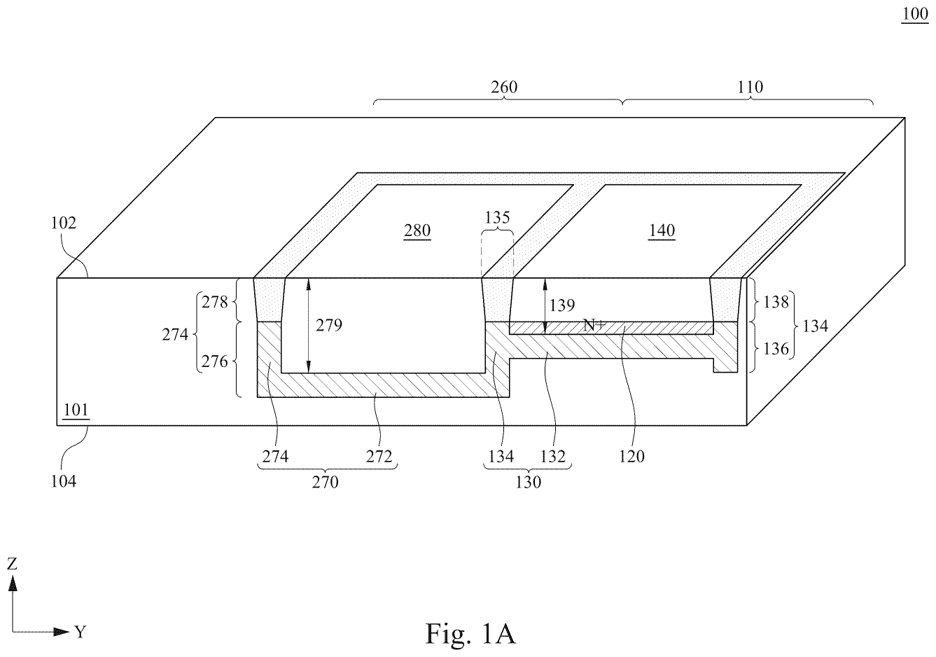

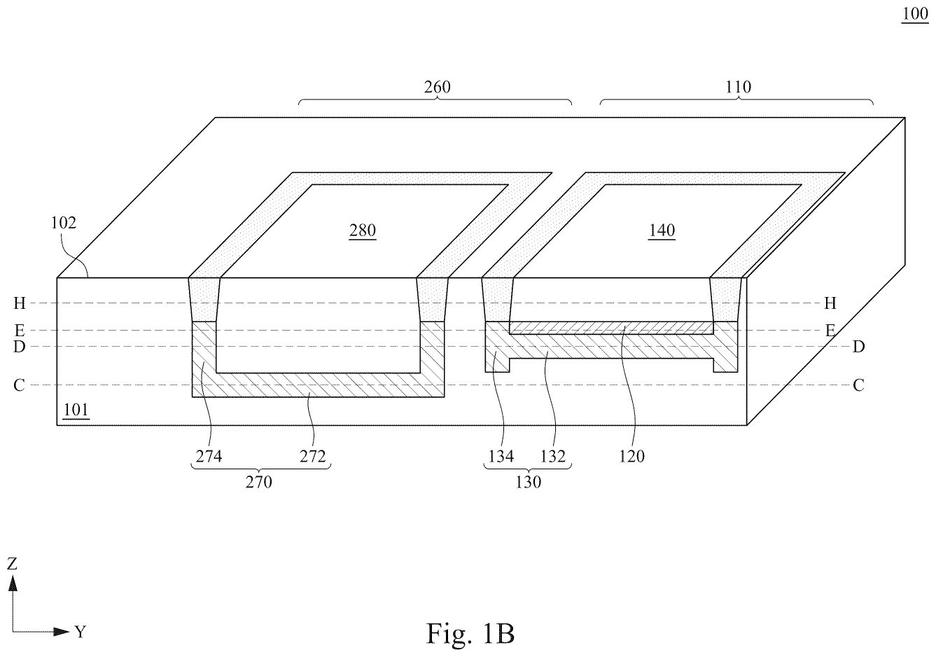

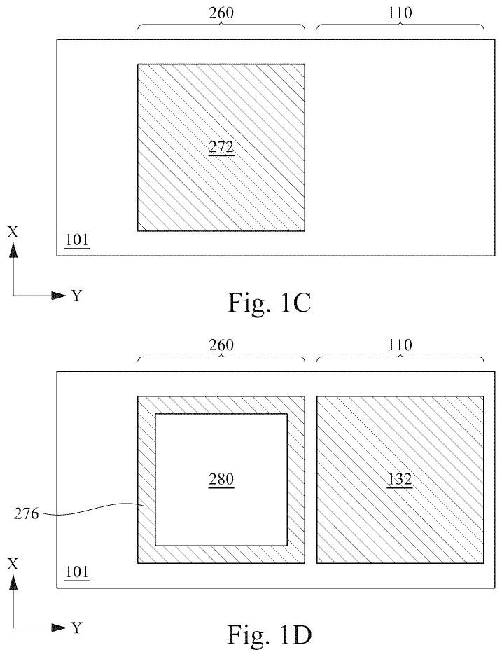

FIGS. 1A-1H are various views of a base substrate that has a deep SOI region and a shallow bias-controlled SOI region which includes a pickup layer, according to some embodiments of the present disclosure. FIG. 1A is a perspective view of a first embodiment where the deep SOI region and the shallow SOI region share a common vertical sidewall. FIG. 1B is a perspective view of a second embodiment where the deep SOI region and the shallow SOI region do not share a common vertical sidewall. FIG. 1C is a plan view through line C-C of FIG. 1B. FIG. 1D is a plan view through line D-D of FIG. 1B. FIG. 1E-1G are plan views of different embodiments through line E-E of FIG. 1B. FIG. 1H is a plan view through line H-H of FIG. 1B.

Referring first to FIG. 1A, the base substrate 100 includes a bulk region 101. The base substrate also has a front side or upper surface 102, and has a back side or lower surface 104. A first deep SOI region 260 and a first shallow bias-controlled SOI region 110 are illustrated on the front side of the base substrate.

The first shallow SOI region 110 includes one or more first pickup layers 120, a first buried dielectric layer 130, and a first semiconducting substrate 140. The first buried dielectric layer 130 separates and electrically isolates the first semiconducting substrate 140 from the bulk region 101. As illustrated here, the first buried dielectric layer 130 is formed from a bottom layer 132 in the X-Y plane and one or more vertical sidewalls 134 that extend upwards in the Z-axis from the bottom layer to the upper surface 102 of the substrate. The number of sidewalls may vary depending on the perspective. For example, the first buried dielectric layer could be described as having four sidewalls which are physically joined together along their edges, or as having one sidewall. As illustrated here, each vertical sidewall 134 is formed from a first portion 136 adjacent the bottom layer and a second portion 138 above the first portion. The second portion extends from the first portion to the upper surface 102 of the base substrate.

The first pickup layer 120 is formed as a layer upon the bottom layer 132 of the first buried dielectric layer. The first pickup layer is doped with a first dopant type (p-type or n-type). Although not illustrated here, it is also contemplated that vertical pickup sidewalls could also be made that extend to the upper surface of the substrate, if desired. The first semiconducting substrate 140 is located within the volume between the upper surface 102 of the base substrate and the first buried dielectric layer 130.

The first semiconducting substrate may also be doped with the first dopant type, and may be referred to as a doped well. The bias of the first semiconducting substrate can be controlled using the first pickup layer. It is noted the dopant concentration in the first pickup layer and the dopant concentration in the first semiconducting substrate may have any desirable ratio.

The deep SOI region 260 includes a buried dielectric layer 270 and a semiconducting substrate 280. The buried dielectric layer 270 separates and electrically isolates the semiconducting substrate 280 from the bulk region 101. The buried dielectric layer 270 is also formed from a bottom layer 272 and one or more vertical sidewalls 274 that extend upwards from the bottom layer to the upper surface 102 of the substrate. Each vertical sidewall 274 is formed from a first portion 276 adjacent the bottom layer and a second portion 278 above the first portion. The deep SOI region does not contain a pickup layer.

The first shallow SOI region 110 has a thickness or depth 139 which can be measured as the distance between the upper surface 102 and the upper surface of the bottom layer 132 of the first buried dielectric layer 130. Similarly, the deep SOI region 260 has a thickness or depth 279 which can be measured as the distance between the upper surface 102 and the upper surface of the bottom layer 272 of the first buried dielectric layer 270. In some embodiments, the thickness 139 of the first shallow SOI region is from about 0.3 micrometers (um) to about 0.6 micrometers. In some embodiments, the thickness 279 of the deep SOI region is from about 1 micrometer to about 6 micrometers. In other embodiments, the difference between the thicknesses 139, 279 is at least 400 nanometers. Other ranges and values are also within the scope of the present disclosure.

The dimensions of the two SOI regions 110, 260 are independent of each other. For example, one region may have a rectangular shape (from a plan view) while the other region has a square shape. Generally, the various layers of each region may have any desired shape (in the plan view).

In the embodiment of FIG. 1A, the first shallow SOI region 110 and the deep SOI region 260 share a common vertical sidewall 135. In the embodiment of FIG. 1B, the first shallow SOI region 110 and the deep SOI region 260 do not share a common vertical sidewall.

Referring now to FIGS. 1C-1H, the cross-sectional view of FIG. 1C shows the bulk region 101 of the base substrate 100 and the bottom layer 272 of the buried dielectric layer in the deep SOI region 260. The bottom layer 272 is solid, without any holes. The bulk region is also present below the first shallow SOI region here.

Next, the cross-sectional view of FIG. 1D shows the semiconducting substrate 280 in the deep SOI region 260 surrounded by the first portion 276 of the vertical sidewall of the buried dielectric layer. The bottom layer 132 of the buried dielectric layer in the first shallow SOI region 110 is also shown. The bottom layer 132 is solid, without any holes.

Higher up, the cross-sectional view of FIG. 1E shows the semiconducting substrate 280 in the deep SOI region 260 still surrounded by the first portion 276. The first pickup layer 120 in the first shallow SOI region 110 is also surrounded by the first portion 136 of the vertical sidewall of the first buried dielectric layer. In this embodiment, the first pickup layer 120 is solid, without any holes. The first pickup layer has a length 125 and a width 127.

Generally, any number of first pickup layers may be present, may have varying dimensions, and may cover whatever surface area is needed. For example, in a second embodiment shown in FIG. 1F, two first pickup layers 120 are illustrated, with a portion of the first semiconducting substrate 140 present between them. Here, only the width 127 of the pickup layers is shorter relative to the embodiment of FIG. 1E. In a third embodiment shown in FIG. 1G, four first pickup layers 120 are illustrated. Here, both the length 125 and the width 127 of each pickup layer is shorter relative to the embodiment of FIG. 1E. In all embodiments, the first pickup layer(s) 120 are surrounded by the first buried dielectric layer 130.

Finally, the cross-sectional view of FIG. 1H shows the semiconducting substrate 280 in the deep SOI region 260 and the first semiconducting substrate 140 of the first shallow SOI region 110. The semiconducting substrates 280, 140 are surrounded by the second portions 138, 278 of the vertical sidewalls of the buried dielectric layers. The upper surface 102 of the base substrate is also indicated.

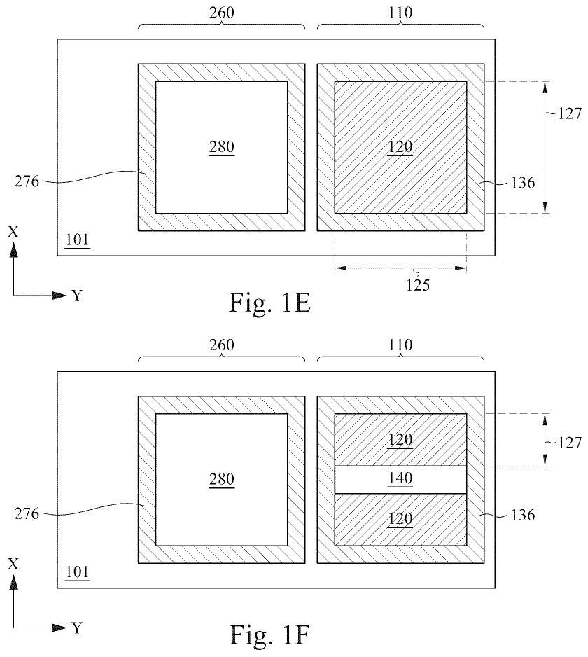

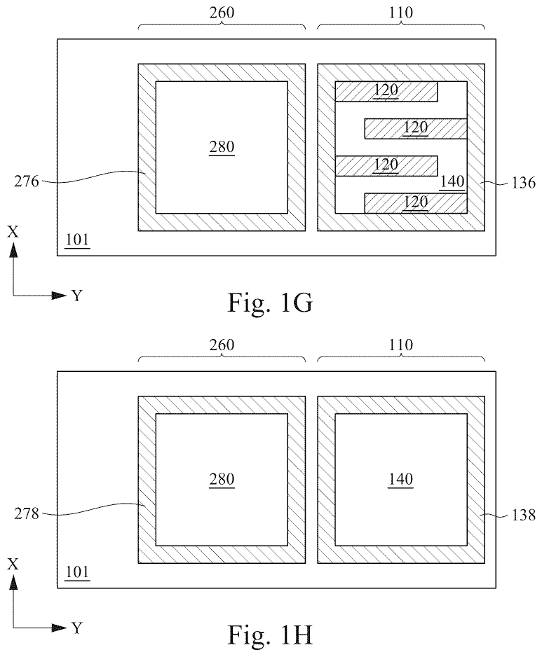

FIG. 2A and FIG. 2B together form a flow chart illustrating a general method 300 for forming SOI regions in a base substrate, in accordance with some embodiments. Some steps of the method are also illustrated in FIGS. 3-17B. These figures provide different views for better understanding. It is noted that in these figures, only Y-axis cross-sectional views are illustrated, and it may be assumed that the X-axis cross-sectional views are similar to the Y-axis views. While the method steps are discussed below in terms of forming a single pickup channel in a single SOI region, such discussion should also be broadly construed as applying to the formation of multiple pickup channels in a single SOI region, or the concurrent formation of multiple SOI regions. Other structures may also be concurrently formed. It is noted that not all steps described in the flow chart are required, and not all method steps are described in the flow chart.

Referring first to FIG. 3, the method begins with a base substrate 100. The base substrate may be, for example, a wafer made of a semiconducting material. Such semiconductor materials can include silicon, for example in the form of crystalline Si. In alternative embodiments, the substrate can be made of other elementary semiconductors such as germanium, silicon carbide (SIC), silicon germanium, or silicon germanium carbide. The substrate may alternatively include a compound semiconductor such as gallium arsenide (GaAs), gallium phosphide, gallium carbide, indium arsenide (InAs), indium phosphide (InP), gallium arsenic phosphide, gallium indium phosphide, cadmium telluride, or cadmium sulfide. In particular embodiments, the substrate is silicon. The base substrate 100 has an upper surface 102 and a lower surface 104, and has a thickness 105 between these two surfaces.

Initially, as indicated in step 302 of FIG. 2A and as illustrated in FIG. 3, a first mask 191 is applied to the base substrate 100. This may be done, for example, by applying a layer of photoresist or a dielectric material (i.e. hard mask) and patterning the layer. Here, a first or deep SOI region 260 is exposed by the first mask.

Next, in step 304 of FIG. 2A and as illustrated in FIG. 3, a first or deep buried dopant layer 200 is formed in the first or deep SOI region 260. This may be performed by ion implantation. In particular embodiments, the primary dopant is oxygen or nitrogen.

Briefly, in ion implantation, an ion implanter is used to implant atoms into a crystal lattice, modifying the conductivity of the lattice in the implanted location. An ion implanter generally includes an ion source, a beam line, and a process chamber. The ion source produces the desired ions. The beam line organizes the ions into a beam having high purity in terms of ion mass, energy, and species. A mask, such as a patterned photoresist layer or a hard mask layer, is used to expose desired regions of the substrate. The ion beam is then used to irradiate the semiconducting wafer substrate in a process chamber. The ion beam strikes the exposed regions on the wafer substrate, and the ions can be implanted into the substrate as dopants at desired depths.

In some embodiments, the primary dopant is implanted at a concentration of about 1×10¹⁵ cm⁻² or greater, such as from about 1×10¹⁵ to about 1×10¹⁹ cm⁻² or from about 5×10¹⁵ to about 5×10¹⁸ cm⁻². In particular embodiments, the primary dopant may be implanted at an energy of about 100 keV to about 600 keV. Other ranges for each of these settings fall within the scope of this disclosure. Any suitable implant angle may be used.

The deep buried dopant layer is formed at depth 279. In particular embodiments, the thickness 201 of the primary dopant-doped layer may be from about 30 nanometers (nm) to about 300 nm. However, other ranges and values are within the scope of the present disclosure.

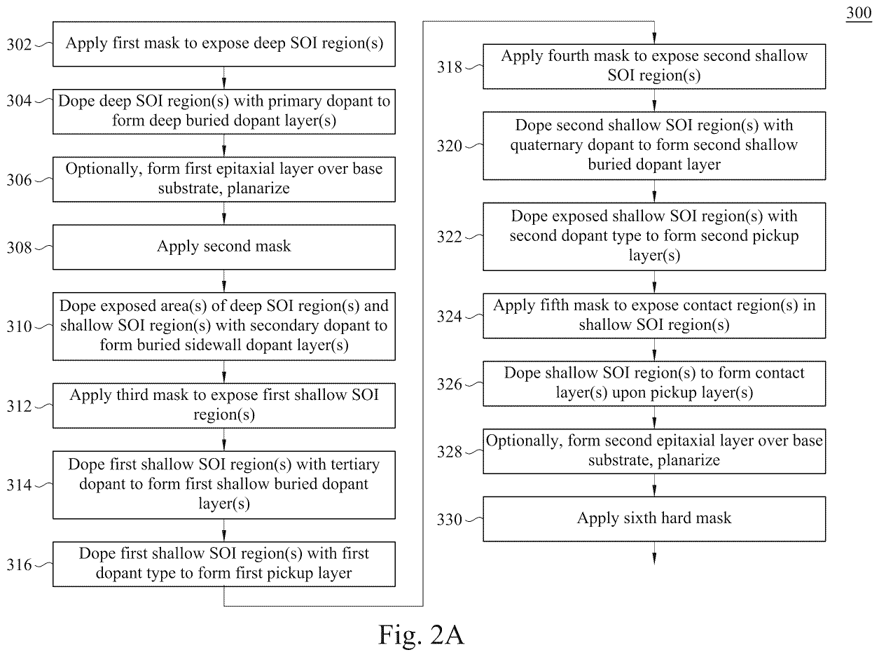

After the first mask is removed, in optional step 306 of FIG. 2A and as illustrated in FIG. 4, a first epitaxial layer 212 is formed upon the upper surface 102 of the base substrate. This may be done, for example, by chemical vapor deposition (CVD), physical vapor deposition (PVD), molecular beam epitaxy (MBE), or other suitable methods. The crystalline orientation of the first epitaxial layer will match that of the base substrate. In particular embodiments, the height or depth 213 of the first epitaxial layer may be from about 30 nanometers (nm) to about 300 nm. However, other ranges and values are within the scope of the present disclosure. The first epitaxial layer may now be considered to form the upper surface of the base substrate.

In this regard, implant uniformity of the primary dopant may be less easily controlled at greater depths, and so it may be desirable to perform step 304 with a thinner base substrate if the depth 279 is relatively great. If desired, planarization may then be performed to obtain a level surface. This may be done, for example, by chemical mechanical polishing (CMP), where the surface of a wafer is leveled using relative motion between the wafer and a rotating polishing pad to which a slurry is applied. Downward pressure is applied to push the wafer against the polishing pad, and elevated elements are worn down to obtain a surface with low surface roughness.

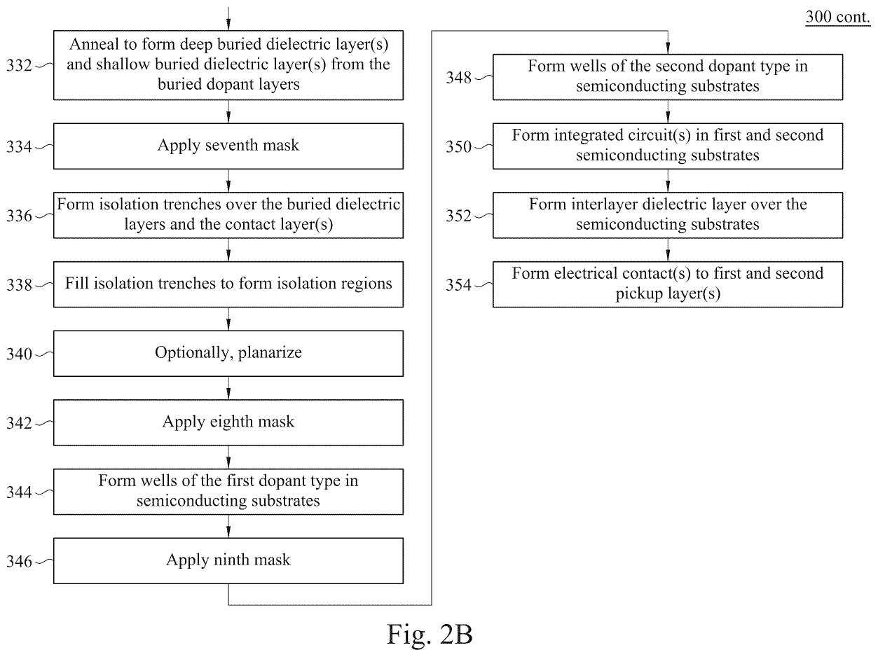

Next, as indicated in step 308 of FIG. 2A and as illustrated in FIG. 5, a second mask 192 is applied to the base substrate. As illustrated here, the upper surface 102 of the base substrate is exposed in desired areas for the formation of vertical sidewalls for the buried dielectric layer(s). As illustrated here, these include areas in both the first or deep SOI region 260, a first shallow SOI region 110, and a second shallow SOI region 112.

Then, in step 310 of FIG. 2A, the exposed areas are doped with a secondary dopant to form buried sidewall dopant layer(s) 202. This may be performed by ion implantation. In particular embodiments, the secondary dopant is oxygen or nitrogen. In this illustration, five separate buried sidewall dopant layer(s) 202 are formed. They are located at a depth 203 that is above the deep buried dopant layer 200, and do not extend to the upper surface 102 of the base substrate. Each sidewall dopant layer has a thickness 205 that may, in particular embodiments, be greater than the thickness 201 of the deep buried dopant layer. It is noted that multiple ion implantation steps may be performed here to deposit the secondary dopant at different depths throughout the base substrate to obtain thickness 205.

In some embodiments, the secondary dopant is implanted at a concentration of about 1×10¹⁵ cm⁻² or greater, such as from about 1×10¹⁵ to about 1×10¹⁹ cm⁻² or from about 5×10¹⁵ to about 5×10¹⁸ cm⁻². In particular embodiments, the secondary dopant may be implanted at an energy of about 50 keV to about 500 keV. Other ranges for each of these settings fall within the scope of this disclosure. Any suitable implant angle may be used.

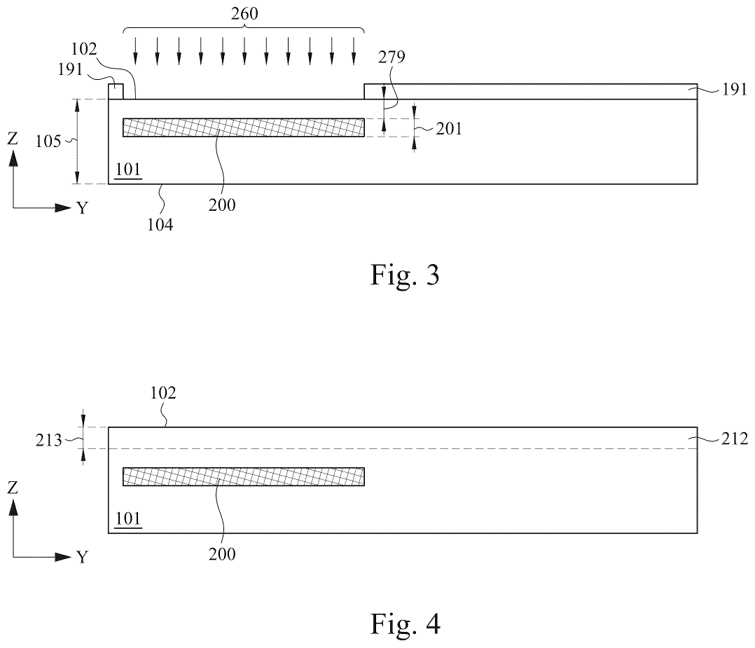

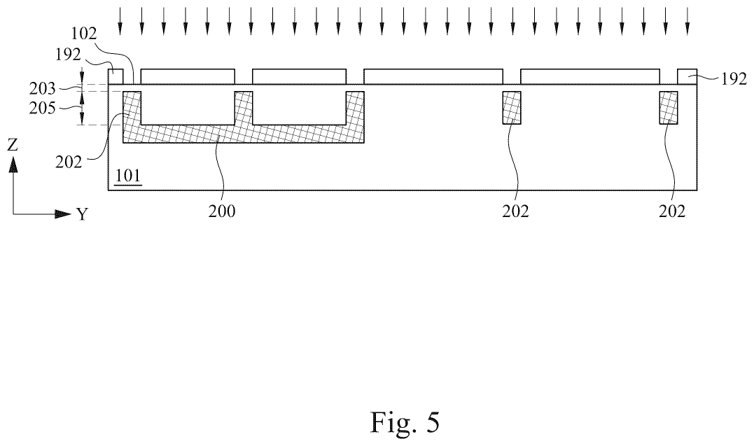

Next, as indicated in step 312 of FIG. 2A and as illustrated in FIG. 6A, a third mask 193 is applied to the base substrate. As illustrated here, only the first shallow SOI region 110 is exposed. The deep SOI region 260 and the second shallow SOI region 112 are not exposed.

Then, in step 314 of FIG. 2A, the first shallow SOI region is doped with a tertiary dopant to form a first shallow buried dopant layer(s) 206 between buried sidewall dopant layers 202. This may be performed by ion implantation. In particular embodiments, the tertiary dopant is oxygen or nitrogen.

The first shallow buried dopant layer 206 is formed at depth 139. In particular embodiments, the thickness 207 of the first shallow buried dopant layer may be from about 30 nanometers (nm) to about 300 nm. However, other ranges and values are within the scope of the present disclosure.

In some embodiments, the tertiary dopant is implanted at a concentration of about 1×10¹⁵ cm⁻² or greater, such as from about 1×10¹⁵ to about 1×10¹⁹ cm⁻² or from about 5×10¹⁵ to about 5×10¹⁸ cm⁻². In particular embodiments, the tertiary dopant may be implanted at an energy of about 50 keV to about 500 keV. Other ranges for each of these settings fall within the scope of this disclosure. Any suitable implant angle may be used.

Next, as indicated in step 316 of FIG. 2A and as illustrated in FIG. 6B, the first shallow SOI region 110 is doped with a first dopant type to form at least one first pickup layer 120 over the first shallow buried dopant layer 206. This may be performed by ion implantation.

In some embodiments, the first dopant type is implanted at a concentration of about 1×10¹⁵ cm⁻² or greater, such as from about 1×10¹⁵ to about 1×10¹⁸ cm⁻². In particular embodiments, the first dopant type may be implanted at an energy of about 20 keV to about 250 keV. Other ranges for each of these settings fall within the scope of this disclosure. Any suitable implant angle may be used. In particular embodiments, the first pickup layer 120 may have a thickness 121 of about 10 nanometers (nm) to about 100 nm. However, other ranges and values are within the scope of the present disclosure.

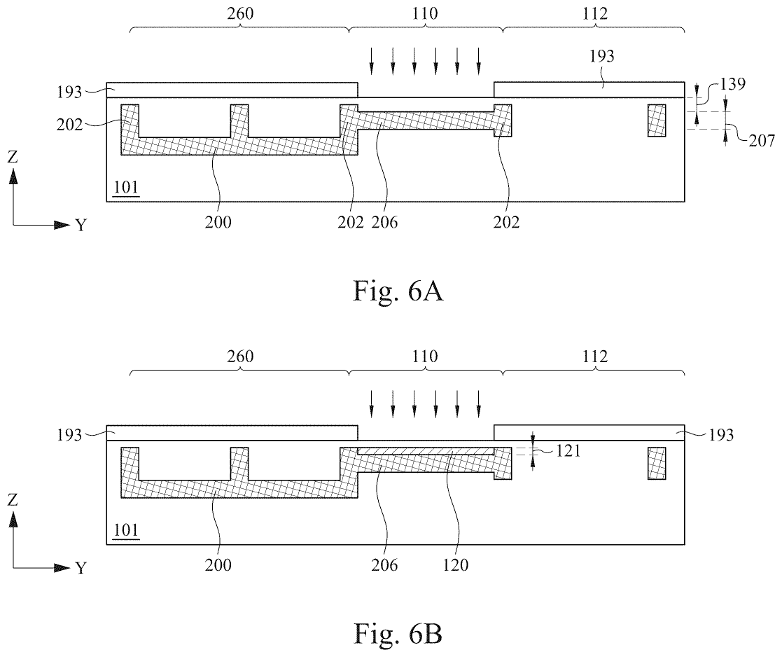

Continuing, the third mask is removed and as indicated in step 318 of FIG. 2A and as illustrated in FIG. 7, a fourth mask 194 is applied to the base substrate. As illustrated here, only the second shallow SOI region 112 is exposed. The deep SOI region 260 and the first shallow SOI region 110 are not exposed.

Then, in step 320 of FIG. 2A and as illustrated in FIG. 7, the second shallow SOI region is doped with a quaternary dopant to form a second shallow buried dopant layer(s) 208. This may be performed by ion implantation. In particular embodiments, the quaternary dopant is oxygen or nitrogen.

The second shallow buried dopant layer 208 is formed at depth 139 between buried sidewall dopant layers 202. In particular embodiments, the thickness 209 of the second shallow buried dopant layer may be from about 30 nanometers (nm) to about 300 nm. However, other ranges and values are within the scope of the present disclosure.

In some embodiments, the quaternary dopant is implanted at a concentration of about 1×10¹⁵ cm⁻² or greater, such as from about 1×10¹⁵ to about 1×10¹⁹ cm⁻² or from about 5×10¹⁵ to about 5×10¹⁸ cm⁻². In particular embodiments, the quaternary dopant may be implanted at an energy of about 50 keV to about 500 keV. Other ranges for each of these settings fall within the scope of this disclosure. Any suitable implant angle may be used. If desired, the first shallow buried dopant layer 206 and the second shallow buried dopant layer 208 may be considered to be a single layer.

Next, as indicated in step 322 of FIG. 2A and as illustrated in FIG. 7, the second shallow SOI region 112 is doped with a second dopant type to form at least one second pickup layer 150 over the second shallow buried dopant layer 208. This may be performed by ion implantation.

In some embodiments, the second dopant type is implanted at a concentration of about 1×10¹⁵ cm⁻² or greater, such as from about 1×10¹⁵ to about 1×10¹⁸ cm⁻². In particular embodiments, the second dopant type may be implanted at an energy of about 20 keV to about 250 keV. Other ranges for each of these settings fall within the scope of this disclosure. Any suitable implant angle may be used. In particular embodiments, the second pickup layer 150 may have a thickness 151 of about 10 nanometers (nm) to about 100 nm. However, other ranges and values are within the scope of the present disclosure.

The first dopant type and the second dopant type are different from each other. If the first dopant type is an n-type dopant, then the second dopant type is a p-type dopant, or vice versa. As illustrated here, the first dopant type is n-type, and the second dopant type is p-type.

Common n-type dopants for silicon substrates may include nitrogen (N), phosphorus (P), arsenic (As), bismuth (Bi), or tantalum (Ta). Common p-type dopants for silicon substrates may include boron (B), aluminum (Al), gallium (Ga), or indium (In). The resulting pickup layers may thus be considered a highly doped semiconductor material or a metal silicide, as appropriate.

It is noted that the first shallow buried dopant layer 206 and the second shallow buried dopant layer 208 of the two shallow SOI regions 110, 112 are formed in two separate steps. The present disclosure also contemplates forming these two layers in the same processing step. However, the steps for forming the first pickup layer 120 and the second pickup layer 150 may require two different masks that only expose one SOI region at a time, which would then require a third mask to expose both SOI regions at the same time.

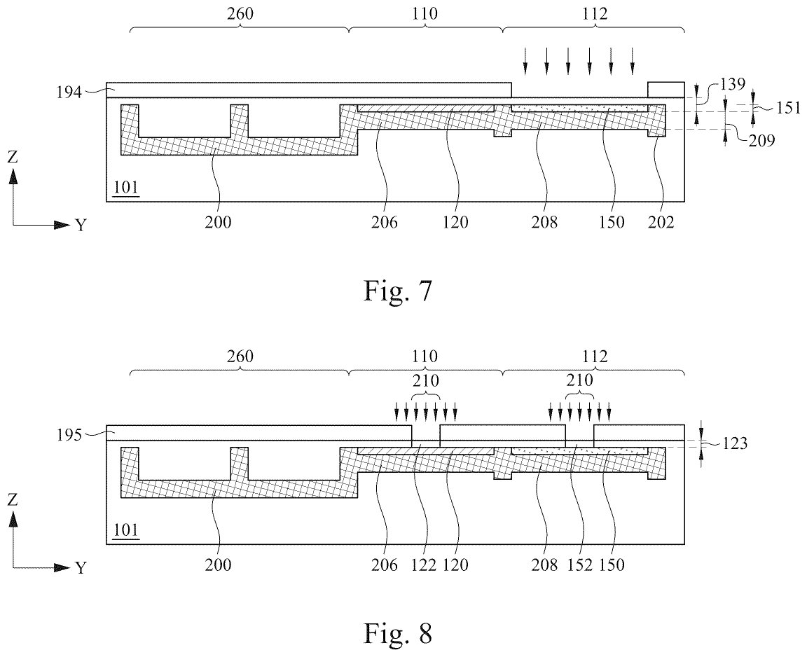

Continuing, the fourth mask is removed and as indicated in step 324 of FIG. 2A and as illustrated in FIG. 8, a fifth mask 195 is applied to the base substrate. The fifth mask only exposes central regions 210 above the two pickup layers 120, 150 within the two shallow SOI regions 210, 212. The deep SOI region 260 is covered. Then, in step 326 of FIG. 2A, the central regions are doped to form contact layers 122, 152 upon each pickup layer 120, 150. Again, this may be performed by ion implantation. Each contact layer is electrically connected to a pickup layer. Desirably, the contact layer is a metal silicide. This permits the contact layer to act as an etch stop layer, and also provides better contact resistance when electrical contacts are formed.

In some embodiments, the dopant for the contact layers is implanted at a concentration of about 1×10¹⁵ cm⁻² or greater, such as from about 1×10¹⁵ to about 1×10¹⁸ cm⁻². In particular embodiments, the dopant may be implanted at an energy of about 20 keV to about 100 keV. Other ranges for each of these settings fall within the scope of this disclosure. Any suitable implant angle may be used. In particular embodiments, the contact layers 122, 152 may independently have a thickness 123 of about 10 nanometers (nm) to about 100 nm. However, other ranges and values are within the scope of the present disclosure.

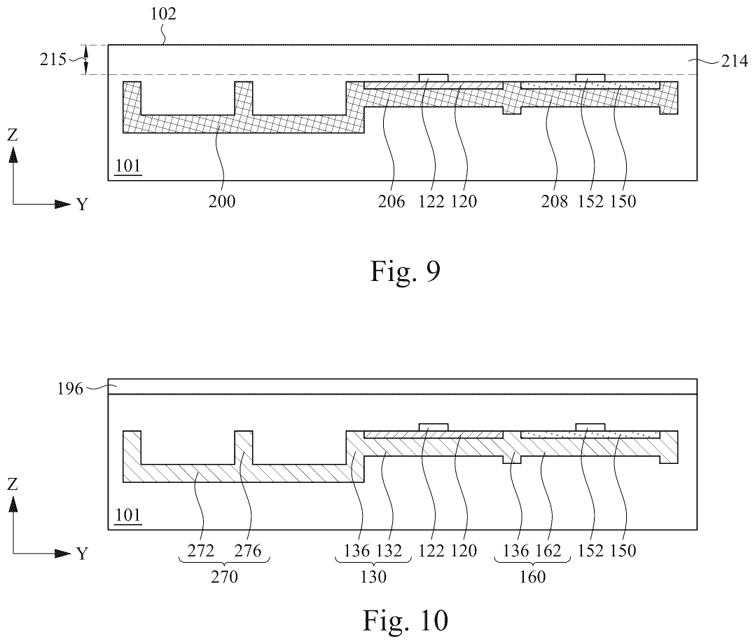

Subsequently, after the fifth mask is removed, in optional step 328 of FIG. 2A and as illustrated in FIG. 9, a second epitaxial layer 214 is formed over the base substrate 100. This may be done as previously described. The crystalline orientation of the second epitaxial layer will match that of the base substrate. In particular embodiments, the height or thickness 215 of the second epitaxial layer may be from about 10 nanometers (nm) to about 300 nm. However, other ranges and values are within the scope of the present disclosure. The second epitaxial layer may now be considered to form the upper surface 102 of the base substrate. Again, planarization may also be performed if desired.

For clarity, it is noted that in some embodiments, the thickness of the base substrate is thin enough that the various doping steps can be done within the base substrate 100 without the need to form the first epitaxial layer 212 and the second epitaxial layer 214.

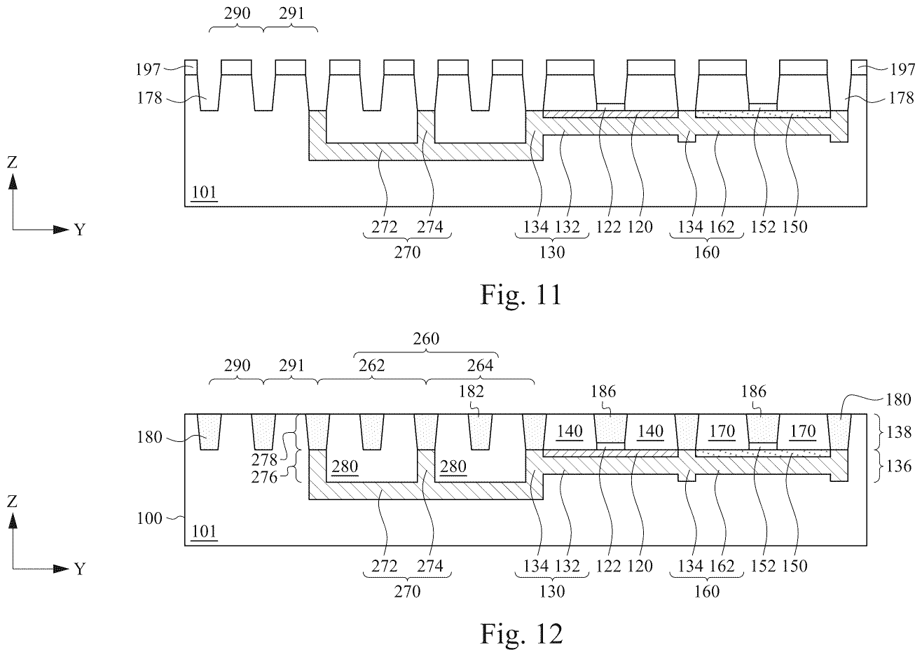

Then, in step 330 of FIG. 2A and as illustrated in FIG. 10, a sixth mask 196 is applied that covers the base substrate. Desirably, the sixth mask is a hard mask formed from a dielectric material (i.e., not photoresist) to protect the surface from impurities. Then, as indicated in step 332 of FIG. 2B, a first or deep buried dielectric layer 270 and at least one shallow buried dielectric layer 130, 160 are formed from the deep buried dopant layer 200, the buried sidewall dopant layer(s) 202, and the shallow buried dopant layers 206, 208. This may be done, for example, by annealing, so that the primary, secondary, tertiary, and quaternary dopants may react with the other material in the base substrate. In some embodiments, the thermal annealing is performed at a temperature from about 900° C. to about 1000° C. The thermal annealing may be performed for a time of about 10 seconds to about 100 minutes. Other temperature and time ranges are also within the scope of this disclosure. The bottom layers 132, 162, 272 and the first portions 136, 276 of the vertical sidewalls of the buried dielectric layer 130, 160, 270 are thus formed. If desired, the shallow buried dielectric layers 130, 160 can be considered a single layer.

The buried dielectric layer(s) may be made of any suitable electrically insulating material. For example, in particular embodiments, the buried dielectric layer is formed from an oxide, such as silicon dioxide, and may be known as a buried oxide layer or BOX layer. However, the buried dielectric layer could also be formed from a nitride, such as silicon nitride. In particular embodiments, it is contemplated the primary, secondary, tertiary, and quaternary dopants are all the same, i.e. all are oxygen or all are nitrogen.

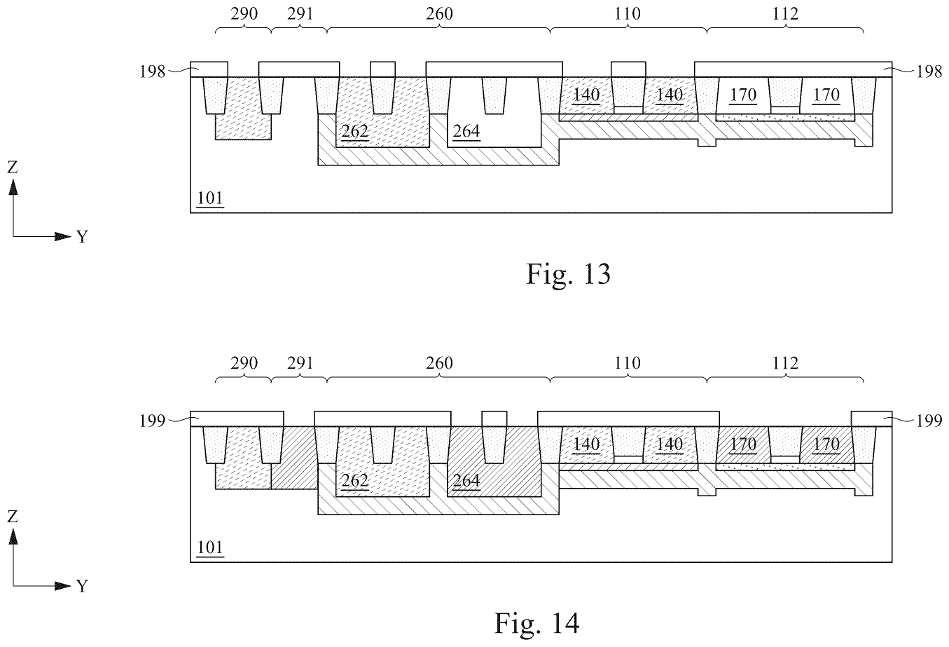

After the sixth mask is removed, in step 334 of FIG. 2B and as illustrated in FIG. 11, a seventh mask 197 is applied over the base substrate 100. The seventh mask will be used to form isolation regions in desired locations. In particular, the areas over the vertical sidewalls 134, 274 and the contact layers 122, 152 are exposed. The base substrate 100 also includes active regions 290, 291 which do not include a buried dielectric layer or a pickup layer. Then, in step 336, isolation trenches 178 are formed in the exposed areas. This is usually done by etching.

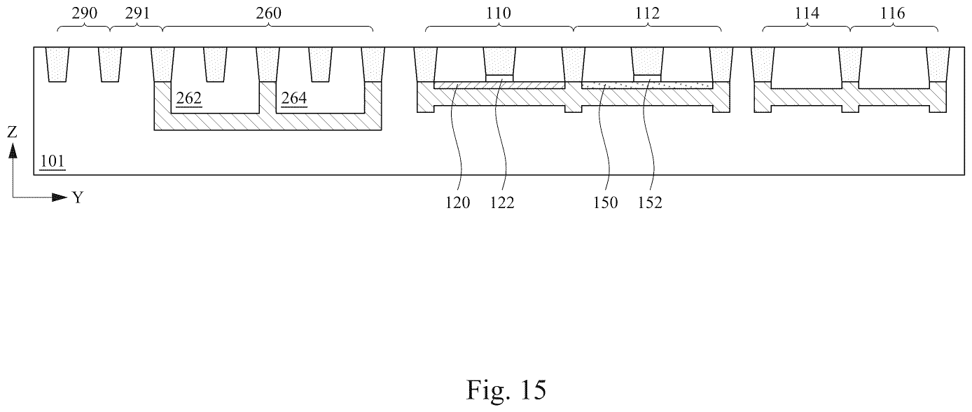

Then, as indicated in step 338 of FIG. 2B and as illustrated in FIG. 12, one or more isolation region(s) 180 are formed within the base substrate 100 by filling the isolation trenches with a dielectric material. The dielectric material in the isolation regions is commonly silicon dioxide, although other dielectric materials can also be used such as undoped polysilicon, silicon nitride, silicon oxynitride, fluoride-doped silicate glass, or another high-k or low-k dielectric material. The deposition can be done using physical vapor deposition (PVD) or chemical vapor deposition (CVD) or spin-on processes known in the art, or can be grown via oxidation. If desired, the dielectric material can be deposited to a level above that of the substrate upper surface 102, then recessed back down to the desired height. These may be considered to be shallow trench isolation (STI) regions. When considered in three dimensions, STI regions in this cross-sectional view may be linked to each other and could be considered as one isolation region (see for example FIG. 1A).

As can be seen here, the first portions 136, 276 of the buried dielectric layers are connected to isolation regions 180 that complete the electrical isolation of the semiconducting substrates 140, 170, 280 from the bulk region 101 of the base substrate. Those isolation regions may be considered to form the second portions 138, 278 of the buried dielectric layers 130, 160, 270. Isolation regions 186 extend down to/are connected to the contact layers 122, 152. As illustrated here, the deep SOI region 260 is divided into a first region 262 and a second region 264. Other isolation regions may be considered inner isolation regions 182 which divide the semiconducting substrate into multiple active regions.

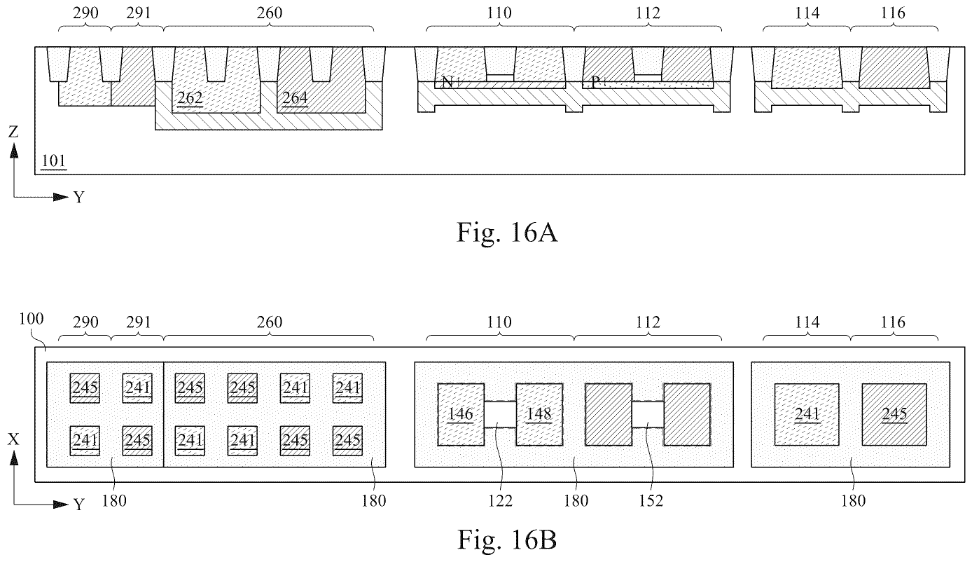

Planarization may also be performed if desired, as indicated in optional step 340 of FIG. 2B. After the seventh mask is removed, in step 342 of FIG. 2B and as illustrated in FIG. 13, an eighth mask 198 is applied that over the base substrate. As illustrated here, the eighth mask covers the second region 264 of the deep SOI region 260, the second shallow SOI region 112, and active region 291. Then, in step 344 of FIG. 2B, the exposed areas are doped with the first dopant type. Here, the first region 262 of the deep SOI region and the first semiconducting substrate 140 are illustrated as being n-doped, and may also be considered to be doped wells. The active region 290 is also n-doped.

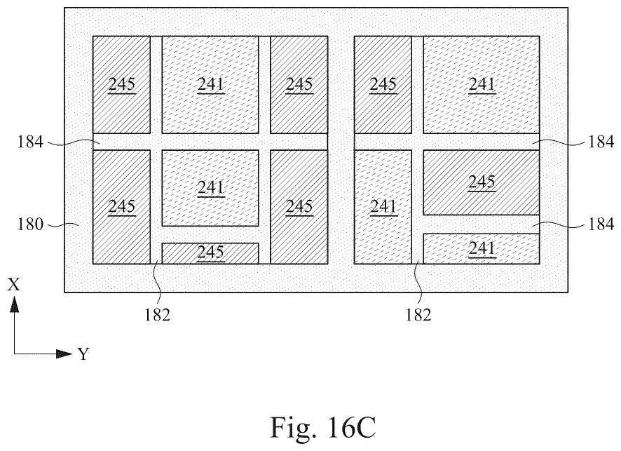

After the eighth mask is removed, in step 346 of FIG. 2B and as illustrated in FIG. 14, a ninth mask 199 is applied over the base substrate. As illustrated here, the ninth mask covers the first region 262 of the deep SOI region 260, the first shallow SOI region 110, and active region 290. Then, in step 348 of FIG. 2B, the exposed areas are doped with the second dopant type. Here, the second region 264 of the deep SOI region and the second semiconducting substrate 170 are illustrated as being p-doped. The active region 291 is also p-doped.

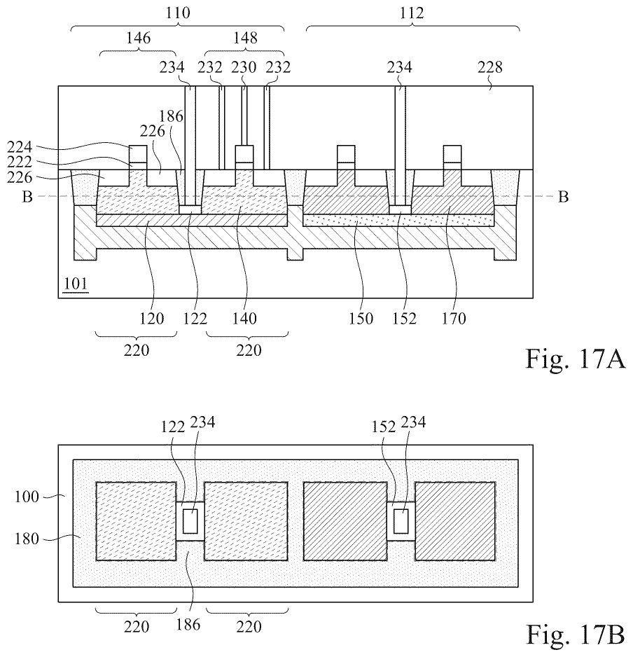

FIG. 15 illustrates another embodiment of the base substrate 100 which falls within the scope of the present disclosure. Two active regions 290, 291 are illustrated which do not have buried dielectric layers. A deep SOI region 260 is divided into two regions 262, 264. No bias control is provided to the deep SOI region. Two bias-controlled shallow SOI regions 110, 112 are illustrated. First pickup layer 120, second pickup layer 150, and contact layers 122, 152 are present, and can be used for bias control. Two non-bias-controlled shallow SOI regions 114, 116 are also illustrated. These two shallow SOI regions do not have pickup layers and thus do not have bias control. The other regions can also be made during the process steps that form the deep SOI region and the bias-controlled SOI regions as described in FIG. 2A and FIG. 2B.

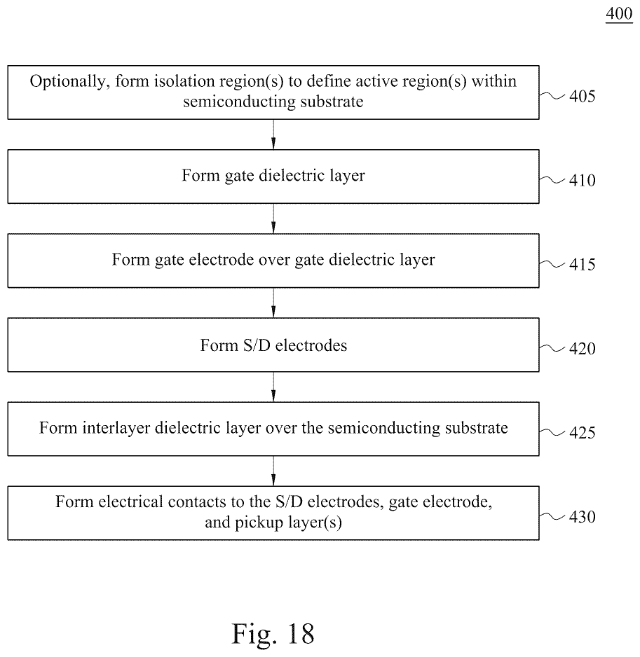

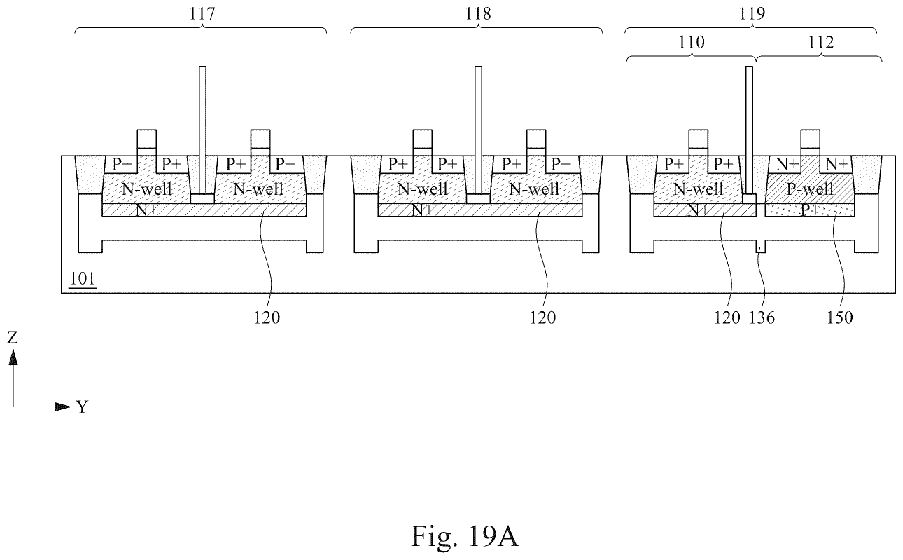

FIG. 16A is a cross-sectional view illustrating the base substrate 100 of FIG. 15 after n-doping and p-doping of the active regions 290, 291, deep SOI region 260, bias-controlled shallow SOI regions 110, 112, and non-bias-controlled shallow SOI regions 114, 116. FIG. 16B is a plan view showing the arrangement of the isolation regions 180 around these regions. As can be seen here, the arrangement of n-doped wells 241 and p-doped wells 245 may vary as desired. Also as illustrated here, contact layer 122 contacts two active regions 146, 148. The shape of first pickup layer 120 is shown in dashed line, and can be described as a barbell shape, with the contact layer 122 being in the area of the “shaft”. Generally, If the two n-doped active regions 146, 148 have the same electrical potential, they can share the same contact layer and pickup layer. Put another way, the ratio of active regions to contact layers/pickup layers does not have to be 1:1, and may be higher if desired.

FIG. 16C is a plan view showing both inner isolation regions 182 that extend in the X-axis and inner isolation regions 184 that extend in the Y-axis. As a result, the pattern of n-doped wells 241 and p-doped wells 245 can be varied as desired. This plan view applies to any of the regions 290, 291, 260, 110, 112, 114, 116.

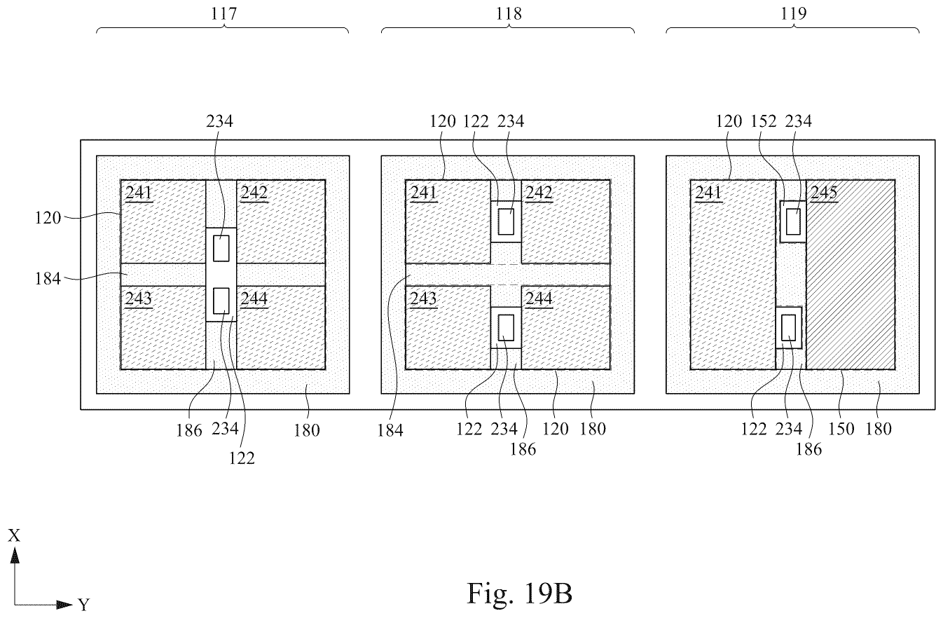

Continuing, in step 350 of FIG. 2B and with reference to FIG. 17A, one or more integrated circuits are formed in the first semiconducting substrate 140 and/or the second semiconducting substrate 170. Next, in step 352, an interlayer dielectric (ILD) layer 228 can be formed over the semiconducting substrates. Then, in step 354, electrical contacts 234 are formed to at least the two pickup layers 120, 150. This may be done by forming vias to the contact layers 122, 152, and then filling the vias with an electrically conductive material. The resulting structure is illustrated in FIG. 17A, which provides a Y-axis cross-sectional view. FIG. 17B provides a plan view of FIG. 17A.

To build integrated circuits, photolithographic patterning processes use ultraviolet light to transfer a desired mask pattern to photoresist. Etching processes may then be used to transfer to the pattern to a layer below the photoresist. This process is repeated multiple times with different patterns of electrically conductive materials and electrically insulating materials to build different conductive, resistive, and/or insulating layers on the wafer substrate. Suitable examples of integrated circuit components may include, for example and without limitation, active components (e.g., transistors), passive components (e.g., capacitors, inductors, resistors, and the like), or combinations thereof.

As illustrated in FIG. 17A, planar transistors 220 are present in the first shallow SOI region 110 and the second shallow SOI region 112. The first shallow SOI region 110 CLEAN is divided into two active regions 146, 148, with a transistor in each active region. As illustrated, the planar transistor 220 includes a gate dielectric layer 222 which is present upon the first semiconducting substrate 140. A gate electrode 224 is located upon the gate dielectric layer 222. Two source/drain (S/D) electrodes 226 are formed in the first semiconducting substrate 140 by doping with the second dopant type. The gate electrode 224 is located between the two source/drain (S/D) electrodes 226. An interlayer dielectric (ILD) layer 228 covers the base substrate 100, including the first shallow SOI region 110 and the second shallow SOI region 112. Electrical contacts 230, 232, 234 are formed to the gate electrode 224, the S/D electrodes 226, and to the first pickup layer 120 through the contact layer 122. An inner isolation region 186 is illustrated as covering the contact layer 122, and also separating the two planar transistors 220 in the first shallow SOI region. The second shallow SOI region has a similar structure.

Referring to the plan view of FIG. 17B, it can be seen that the isolation region 180 surrounds the two transistors 220 on three sides, with the inner isolation region 186 forming a fourth side around the two transistors. It should be noted that the various isolation regions 180, 186 and the buried dielectric layers 130, 160 can be the same material.

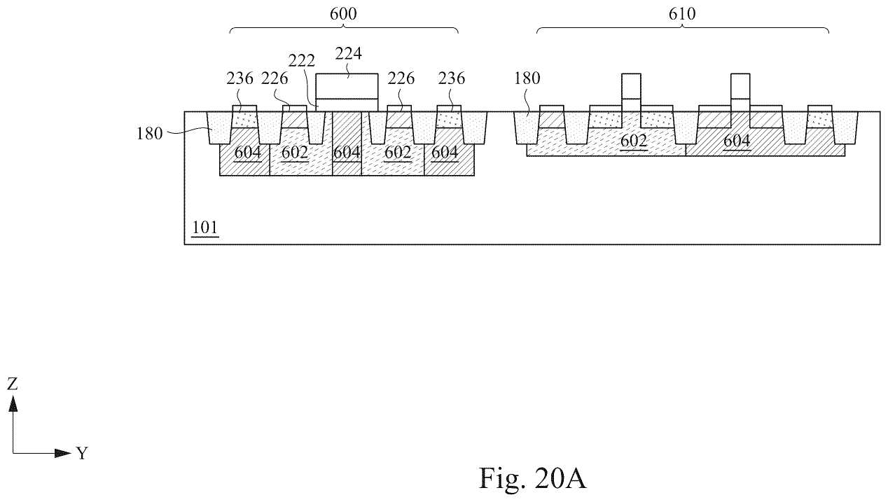

FIG. 18 is a flow chart illustrating a method 400 for forming a semiconducting device in an SOI region, in accordance with some embodiments. The method is discussed with reference to FIG. 17A and FIG. 17B. While the method steps are discussed below in terms of forming a single device in a single SOI region, such discussion should also be broadly construed as applying to the concurrent formation of multiple devices in a single SOI region or multiple SOI regions. The method also describes formation of a planar transistor or an LDMOS transistor, but can be suitably adapted to form other devices. Other structures may also be concurrently formed. It is noted that not all steps described in the flow chart are required.

The method begins with optional step 405 of FIG. 18, where one or more isolation regions can be formed within the semiconducting substrate 140 if desired to define active regions (assuming this was not already previously done). Next, in step 410, a gate dielectric layer 222 is formed upon the semiconducting substrate 140. Again, CVD, PVD, atomic layer deposition (ALD), ion implantation, or other suitable deposition process may be used to form the gate dielectric layer. The gate dielectric layer 222 is formed between the isolation regions 180, 186. Afterwards, in step 415, a gate electrode 224 is formed upon the gate dielectric layer 222. This may be done by CVD, PVD, or other suitable process. If desired, a gate spacer (not shown) may be formed upon the sidewalls of the gate electrode 224. Then, in step 420, source/drain (S/D) electrodes 226 are formed on opposite sides of the gate electrode 224. They may be formed using ion implantation or other suitable methods to dope the semiconducting substrate, or by patterning and deposition of suitable metals. Next, in step 425 of FIG. 18, an interlayer dielectric (ILD) layer 228 is formed over the substrate. Then, in step 430, electrical contacts 230, 232, 234 are formed to the gate electrode 224, the two S/D electrodes 226, and the pickup channels 120, 150. This may be done by forming vias, and then filling the vias with an electrically conductive material.

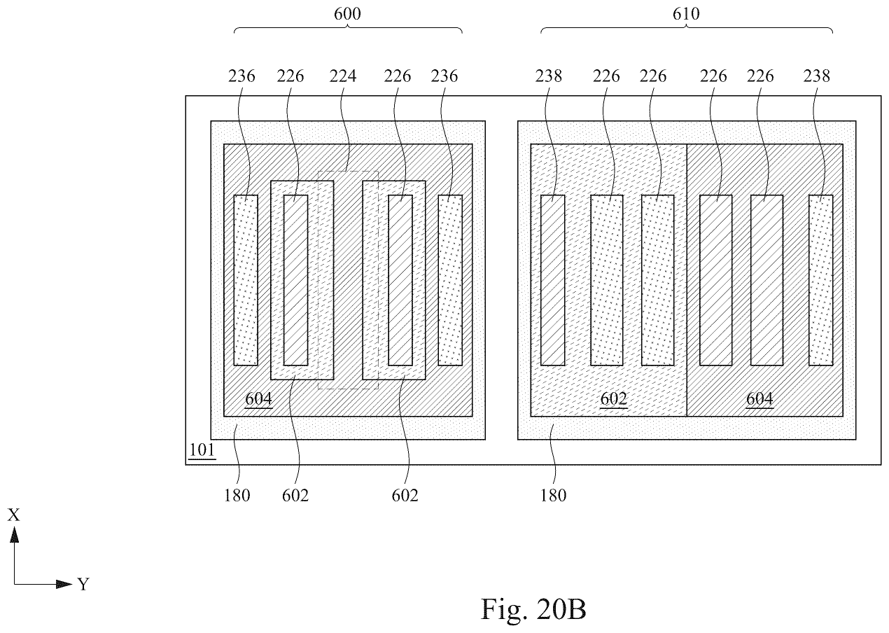

FIG. 19A and FIG. 19B are additional variations of a shallow bias-controlled SOI region, according to some embodiments of the present disclosure. FIG. 19A provides a Y-axis cross-sectional view. FIG. 19B provides a plan view. In these views, the shape of the first pickup layer 120/second pickup layer 150 are shown in dashed line.

In the first embodiment 117, four active regions 241, 242, 243, 244 are formed in the first semiconducting substrate 140 by inner isolation regions 184, 186. As seen in the plan view, the contact layer 122 contacts each active region, and two electrical contacts 234 are illustrated to the contact layer.

In the second embodiment 118, again, four active regions 241, 242, 243, 244 are formed in the first semiconducting substrate 140 by inner isolation regions 186, 184. Here, two first pickup layers 120 are present, were each pickup layer contacts two of the active regions and does not contact the other two active regions. As seen in the plan view, two contact layers 122 are present, one contact layer for each first pickup layer. One electrical contact 234 is illustrated to each contact layer 122.

In the third embodiment 119, the first shallow SOI region 110 includes an n-doped active region 241 and the second shallow SOI region 112 includes a p-doped active region 245. The first portion 136 of the vertical sidewall between the two pickup layers 120, 150 is S-shaped. First contact layer 122 and second contact layer 152 are CLEAN both located between the two SOI regions 110, 112, and can be described as being covered by a common isolation region 186. One electrical contact 234 is illustrated to each contact layer 122, 152.

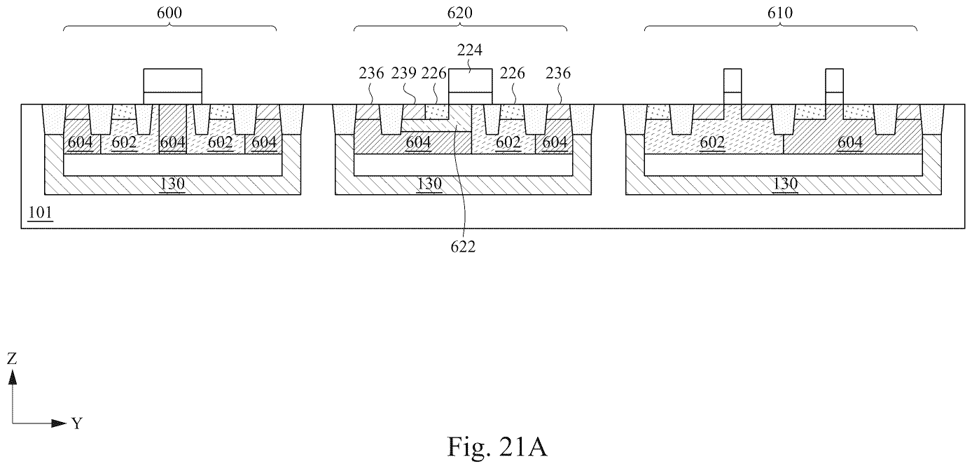

FIG. 20A and FIG. 20B illustrate some integrated circuits which can be present in an active region 290 in the base substrate 100, according to some embodiments of the present disclosure. FIG. 20A provides a Y-axis cross-sectional view. FIG. 20B provides a plan view. It is noted that isolation regions 180 visible in FIG. 20A are not shown in FIG. 20B so the other components (which may be buried below the isolation region) are visible.

The first integrated circuit 600 is a high-voltage metal-oxide semiconductor (HVMOS) transistor. As better seen in the plan view of FIG. 20B, two n-wells 602 (drift regions) are surrounded by a p-well 604. The gate dielectric layer 222 and the gate electrode 224 span the two n-wells, with a portion of the p-well between them. S/D electrodes 226 and pick-up electrodes 236 are also illustrated.

The second integrated circuit 610 is a core or I/O metal-oxide semiconductor (MOS) transistor. Here, transistors are formed in an n-well 602 and a p-well 604. S/D electrodes 226 are shown, as well as bias electrodes 238.

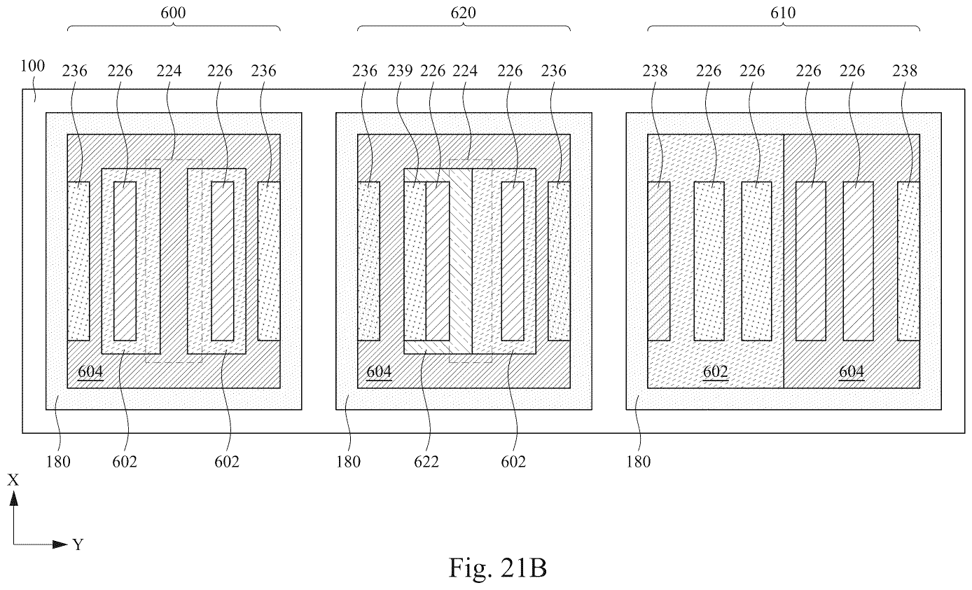

FIG. 21A and FIG. 21B illustrate some integrated circuits which can be present in a non-bias-controlled SOI region 114 in the base substrate 100, according to some embodiments of the present disclosure. FIG. 21A provides a Y-axis cross-sectional view. FIG. 21B provides a plan view. Again, isolation regions 180 visible in FIG. 21A are not shown in FIG. 21B to show the other components. All three embodiments include a buried dielectric layer 130, and do not include a pickup layer.

The first integrated circuit 600 on the left-hand side is a high-voltage metal-oxide semiconductor (HVMOS) transistor, and has the same structure as described with respect to FIG. 20A and FIG. 20B. The second integrated circuit 610 on the right-hand side is a core or I/O metal-oxide semiconductor (MOS) transistor, and also has the same structure as described with respect to FIG. 20A and FIG. 20B.

The third integrated circuit 620 in the center is a laterally-diffused metal-oxide semiconductor (LDMOS) transistor. An n-well 602 is surrounded by a p-well 604. A P-body 622 is present in the portion of the p-well underneath the gate electrode 224. S/D electrodes 226 are present, along with a body contact 239 in the p-body. Pick-up electrodes 236 also contact the p-well.

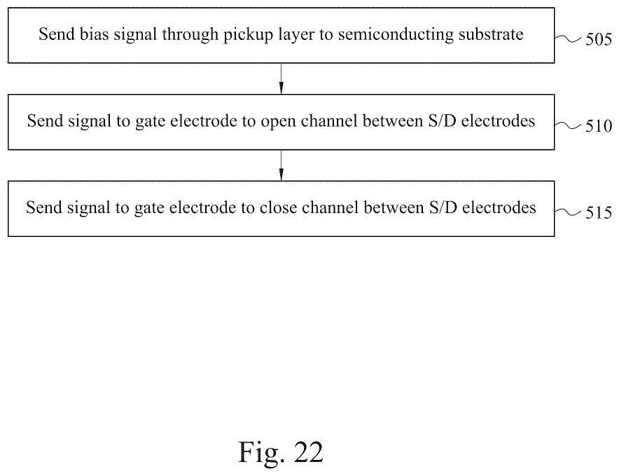

FIG. 22 is a flow chart illustrating a method 500 for operating a transistor in a bias-controlled SOI region, in accordance with some embodiments. The method steps are discussed below in terms of using a single transistor and a single bias-controlled SOI region, and should also be broadly construed as applying to the concurrent use of multiple transistors and/or multiple SOI regions. Reference is also made to the structure of FIG. 17A.

In step 505 of FIG. 22, a bias signal is sent through the first pickup layer 120 to the semiconducting substrate 140. This is typically a current or voltage signal, which changes the bias of the semiconducting substrate. In step 510, a signal is sent to the gate electrode 224. Typically, a voltage signal is sent to the gate electrode, either in the form of an increased voltage or a decreased voltage (depending on how the gate electrode is operated). This opens a channel (not illustrated) between the S/D electrodes 226, which permits current to flow between them. The bias signal aids in stabilizing the transistor so that the transistor performance varies very little when operating conditions change. In step 515 of FIG. 22, a different signal is sent to the gate electrode 224 to close the channel, causing current flow to end. Integrated circuits that are not bias-controlled do not receive a bias signal.

It is also noted that certain process steps are not expressly described in the discussion above. For example, a pattern/structure may be formed in a given layer by applying a photoresist layer, patterning the photoresist layer, developing the photoresist layer to form a mask, and then etching through the mask to transfer the pattern to the given layer.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern (i.e. a mask). One example of a common developer is aqueous tetramethylammonium hydroxide (TMAH). Generally, any suitable developer may be used. Sometimes, a post develop bake or “hard bake” may be performed to stabilize the photoresist pattern after development, for optimum performance in subsequent steps.

Continuing, portions of the given layer below the patterned photoresist mask are now exposed. Etching transfers the photoresist pattern to the given layer below the patterned photoresist mask. After use, the mask can be removed, for example, using various solvents such as N-methyl-pyrrolidone (NMP) or alkaline media or other strippers at elevated temperatures, or by dry etching using oxygen plasma.

Generally, any etching step described herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

The base substrates may be incorporated into larger semiconductor packages and into larger devices. Such packages may also include various interconnect structures for communicating with other semiconductor devices. The semiconductor devices may be useful in amplifiers; power management devices; BCD (Bipolar-CMOS-DMOS) circuits for driving discrete high voltage components; image signal processors (ISP); LCD, OLED, AMOLED, or QLED display panels; image sensors that can be used in systems such as mobile telephones, facial recognition systems, or as motion sensors for automotive applications, security applications, energy efficiency, etc.

The substrates of the present disclosure having bias-controlled SOI regions have several advantages. Full electrical isolation provides better device performance and permits withstanding of higher voltage, which is useful for high-voltage applications. Parasitic capacitance is also reduced. The substrates can be completed using foundry in-house processes with current semiconductor process tools. There is no area loss due to the need for H-body contacts. The structures are flexible and permit different designs as needed. The structures are detectable. Separate high-priced SOI substrates do not need to be used, and bulk devices and SOI devices can be built on the same base substrate.

Some embodiments of the present disclosure thus relate to methods for making a multi-SOI substrate, in particular a base substrate with at least one deep SOI region and at least one shallow bias-controlled SOI region. The deep SOI region of the base substrate is doped with a primary dopant to form a deep buried dopant layer. The deep SOI region and a first shallow SOI region are then doped with a secondary dopant to form one or more buried sidewall dopant layers. The first shallow SOI region is doped with a tertiary dopant to form a first shallow buried dopant layer. The first shallow SOI region is then doped with a first dopant type to form a first pickup layer. The first shallow SOI region is then doped to form a first contact layer electrically connected to the first pickup layer. Then, a deep buried dielectric layer and a first shallow buried dielectric layer are formed from the deep buried dopant layer, the one or more buried sidewall dopant layers, and the first shallow buried dopant layer, for example by annealing. Isolation regions are formed which are connected to vertical sidewalls of the deep buried dielectric layer and the first shallow buried dielectric layer to form at least one semiconducting substrate in the deep SOI region and at least one semiconducting substrate in the first shallow SOI region that are electrically isolated from the base substrate. The first pickup layer provides bias control.

Other embodiments disclosed herein relate to a first bias-controlled SOI region of a base substrate. The first bias-controlled SOI region comprises a buried dielectric layer within the base substrate, a pickup layer, and a semiconducting substrate above the pickup layer which is electrically isolated from the base substrate by the buried dielectric layer. The pickup layer is located upon the buried dielectric layer. A contact layer is electrically connected to the pickup layer. An isolation region is present above and connected to the contact layer.

Also described in various embodiments herein are methods for forming a multi-SOI substrate, in particular a base substrate with two SOI regions, one including an n-doped pickup layer and the other including a p-doped pickup layer. A first SOI region and a second SOI region are doped to form one or more buried sidewall dopant layers. The first SOI region and the second SOI region are then doped to form a buried dopant layer. The first SOI region is doped with a first dopant type to form a first pickup layer. The second SOI region is doped with a second dopant type to form a second pickup layer. The first SOI region and the second SOI region are doped to form a first contact layer electrically connected to the first pickup layer and a second contact layer electrically connected to the second pickup layer. Annealing is performed to form a buried dielectric layer from the one or more buried sidewall dopant layers and the buried dopant layer. Isolation regions are formed that are connected to vertical sidewalls of the buried dielectric layer to form a first semiconducting substrate in the first SOI region and a second semiconducting substrate in the second SOI region that are electrically isolated from the base substrate. At least one isolation region is formed over the first contact layer and the second contact layer.

Methods for concurrently forming a shallow bias-controlled SOI region and a shallow non-bias controlled SOI region are also disclosed. Generally, a pickup layer is formed in the shallow bias-controlled SOI region as described above. The shallow non-bias-controlled SOI region includes a buried dielectric layer and a semiconducting substrate, which are formed in the base substrate concurrently with their formation in the shallow bias-controlled SOI region. Integrated circuits may be concurrently formed in both regions. The resulting structures are also disclosed.

Methods for concurrently forming a shallow bias-controlled SOI region and a doped active region in the base substrate are also disclosed. The shallow bias-controlled SOI region is formed as described above. The active region is concurrently doped when the semiconducting substrate in the shallow bias-controlled SOI region is doped. Isolation regions are also concurrently formed in the shallow bias-controlled SOI region and the active region. Integrated circuits may be concurrently formed in both regions. The resulting structures are also disclosed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for forming a multi-SOI substrate, comprising:
doping a first SOI region of a base substrate with a primary dopant to form a first buried dopant layer;
doping the first SOI region and a first shallow SOI region with a secondary dopant to form one or more buried sidewall dopant layers;
doping the first shallow SOI region with a tertiary dopant to form a first shallow buried dopant layer;
doping the first shallow SOI region with a first dopant type to form a first pickup layer;
doping the first shallow SOI region to form a first contact layer electrically connected to the first pickup layer;
forming a first buried dielectric layer and a first shallow buried dielectric layer from the first buried dopant layer, the one or more buried sidewall dopant layers, and the first shallow buried dopant layer; and
forming isolation regions connected to vertical sidewalls of the first buried dielectric layer and the first shallow buried dielectric layer to form at least one semiconducting substrate in the first SOI region and at least one semiconducting substrate in the first shallow SOI region that are electrically isolated from the base substrate.

2. The method of claim 1, further comprising forming an isolation region over and extending down to the first contact layer.

3. The method of claim 1, further comprising forming a first epitaxial layer over the base substrate after forming the first buried dopant layer.

4. The method of claim 1, further comprising forming a second epitaxial layer over the base substrate after forming the first contact layer.

5. The method of claim 1, wherein the first SOI region and the first shallow SOI region share a common vertical sidewall.

6. The method of claim 1, wherein the primary dopant, the secondary dopant, and the tertiary dopant are identical.

7. The method of claim 1, wherein the first buried dielectric layer and the first shallow buried dielectric layer are formed by annealing the base substrate.

8. The method of claim 7, wherein the annealing is performed at a temperature of about 900° C. to about 1000° C.

9. The method of claim 1, wherein the at least one semiconducting substrate in the first SOI region has a thickness of about 1 micrometer to about 6 micrometers, and the at least one semiconducting substrate in the first shallow SOI region has a thickness of about 0.3 micrometers to about 0.6 micrometers; or wherein the first buried dopant layer and the first shallow buried dopant layer differ in depth by at least 400 nanometers.

10. The method of claim 1, further comprising forming one or more electrical contacts to the first contact layer.

11. The method of claim 1, further comprising forming at least one transistor in the first shallow SOI region.

12. The method of claim 1, further comprising:
doping a second shallow SOI region with the secondary dopant;
doping the second shallow SOI region with a quaternary dopant to form a second shallow buried dopant layer;
doping the second shallow SOI region with a second dopant type to form a second pickup layer;
doping the second shallow SOI region to form a second contact layer electrically connected to the second pickup layer;
forming a second shallow buried dielectric layer from the one or more buried sidewall dopant layers and the second shallow buried dopant layer; and
forming isolation regions connected to vertical sidewalls of the second shallow buried dielectric layer to form at least one semiconducting substrate in the second shallow SOI region that is electrically isolated from the base substrate.

13. A multi-SOI structure, comprising:
a first bias-controlled SOI region of a base substrate, the first bias-controlled SOI region comprising:
a buried dielectric layer within the base substrate;
a pickup layer upon the buried dielectric layer;
a semiconducting substrate above the pickup layer which is electrically isolated from the base substrate by the buried dielectric layer;
a contact layer electrically connected to the pickup layer; and
an isolation region above and connected to the contact layer.

14. The structure of claim 13, wherein the semiconducting substrate comprises a first active region and a second active region, and the pickup layer electrically contacts both the first active region and the second active region.

15. The structure of claim 13, wherein the semiconducting substrate comprises a first active region and a second active region, and the pickup layer electrically contacts only the first active region and does not electrically contact the second active region.

16. The structure of claim 13, further comprising a second bias-controlled SOI region electrically isolated from the first bias-controlled SOI region, wherein the pickup layer and the semiconducting substrate of the first bias-controlled SOI region are doped with a first dopant type, and wherein the pickup layer and the semiconducting substrate of the second bias-controlled SOI region are doped with a second dopant type that is different from the first dopant type.

17. The structure of claim 16, wherein the contact layer of the first bias-controlled SOI region and the contact layer of the second bias-controlled SOI region share a common isolation region.

18. The structure of claim 13, further comprising a deep SOI region of the base substrate, the deep SOI region comprising a deep buried dielectric layer within the base substrate that electrically isolates a deep SOI semiconducting substrate from the base substrate.

19. A method for forming a multi-SOI substrate, comprising:
doping a first SOI region and a second SOI region to form one or more buried sidewall dopant layers;
doping the first SOI region and the second region to form a buried dopant layer;
doping the first SOI region with a first dopant type to form a first pickup layer;
doping the second SOI region with a second dopant type to form a second pickup layer;
doping the first SOI region and the second SOI region to form a first contact layer electrically connected to the first pickup layer and a second contact layer electrically connected to the second pickup layer;
annealing to form a buried dielectric layer from the one or more buried sidewall dopant layers and the buried dopant layer;
forming isolation regions connected to sidewalls of the buried dielectric layer to form a first semiconducting substrate in the first SOI region and a second semiconducting substrate in the second SOI region that are electrically isolated from the a base substrate; and
forming at least one isolation region over the first contact layer and the second contact layer.

20. The method of claim 19, wherein the at least one isolation region covers both the first contact layer and the second contact layer.
